(19) United States
(12) Patent Application Publication
(10) Pub. No.: US 2015/0084663 A1
(43) Pub. Date: Mar. 26, 2015

(54) METHOD AND APPARATUS FOR DETECTING DISCONTINUITUES IN A SOLAR ARRAY

(71) Applicant: DOW GLOBAL TECHNOLOGIES LLC, Midland, MI (US)

(72) Inventors: Douglas J. Wirsing, Midland, MI (US); Michael J. Lesniak, Kawkawlin, MI (US); John T. Horwath, Bay City, MI (US)

(21) Appl. No.: 14/397,766

(22) PCT Filed: Apr. 10, 2013
(86) PCT No.: PCT/US13/35932

§ 371 Date: Oct. 29, 2014

Related U.S. Application Data
(60) Provisional application No. 61/658,649, filed on Jun. 12, 2012.

(51) Int. Cl. H02S 50/10; G01R 31/40

(52) U.S. Cl. CPC H02S 50/10; G01R 31/40
USPC 324/761.01

(57) ABSTRACT

A method of detecting a discontinuity in: a solar array (10) comprising: locating a detecting device (200) in one or more working positions (56) along the solar array: inducing a signal (80) by applying a plurality of flashes of light to a solar module in the solar array: measuring (64) the signal at two different locations along the solar array; comparing the signals measured at two different locations to each other, and outputting (62) a result of the comparing step.

### FIELD

The present teachings relate to a method and apparatus for detecting open circuits (i.e., discontinuities) located in a solar module, between solar modules, between a solar module and an integrated flashing piece, or other locations along the solar array.

### BACKGROUND

The present teachings are predicated upon providing an improved method and apparatus for detecting discontinuities and/or partial discontinuities in a solar array. Each solar array is comprised of a combination of solar modules, connection devices, and integrated flashing pieces. Once all of the pieces are combined together a solar array is formed and power is passed from the solar array to an inverter so that the power may be used. Generally, each solar module, connection device, and integrated flashing piece includes two buss bars adding to the points of contact in the solar array. Depending upon the number of solar modules a solar array can have as many as 600 connection points or more. If these connections fail, power from the solar array to the inverter is reduced and/or eliminated. When this condition occurs it can be difficult to isolate the exact location of the cause of the reduction and/or elimination of power from the solar array to the inverter. Adding to the difficulty in detecting the exact location of the discontinuity are that the solar array may be located in a loud environment such as next to an airport or a factory; in hard to reach locations such as roof tops; or the like.

Devices and methods to detect the discontinuities exist; however, some of these devices may be too large and/or expensive to use in an “on-site” location such as a roof top. Generally, many of these devices require the device to be electrically connected to the solar array so that the device can monitor a signal through the solar array. Electrically connecting the device to the solar array can be time consuming as well as difficult due to the location of some solar arrays, and exposes the user to a risk of electrical shock. Some attempts have been made to create non-contact detection devices. However, these devices require a large amount of user input to determine whether the connection point being measured is continuous, discontinuous, or a state therebetween. Haste and/or loss of attention by the user, surrounding environmental conditions, or both may lead to inaccurate readings and/or multiple attempts to locate a discontinuity and/or partial discontinuity. In another example non-contact devices may detect radiated energy from other sources around the solar array such as machinery, appliances, motors, other electric device, or the like that may operate within a similar frequency range, or a combination thereof. These devices may not be able to filter out these other radiated energy sources and may provide erroneous readings due to these other radiated energy sources. Further, some of these devices have difficulty in detecting partial discontinuities. Examples of devices and/or methods used to locate discontinuities in a solar array may be found in U.S. Pat. Nos. 3,696,286; 4,695,788; and 6,979,771; U.S. Patent Application Publication Nos. 2003/0059966 and 2010/0236035; International Patent Nos. WO87/07731; WO97/14047; WO98/32024; WO2006/076893; WO2007/076846; and Progressive Electronic 200EP Induction Amplifier available at: http://www.amazon.com/Progressive-Electronic-Inductive-Amplifier-Tracer/dp/B007M2BZJY, all of which are incorporated by reference herein for all purposes.

It would be attractive to have a device and/or method that provides an output regarding whether the tested locations are continuous, discontinuous, or partially discontinuous. It would be attractive to have a detection device and method that are free of electrical contact with the solar array so that the detection device can test a location without being in electrical contact with the solar array. What is needed is a detection device that is portable so that all of the pieces of the device may be located proximate to the solar array. What is further needed is a method of tuning a detection device with the solar array so that the signal from a signal source, a signal measured by the signal detector, or both may be adjusted so that discontinuities and/or partial discontinuities are accurately detected by the signal detector.

### SUMMARY

The present teachings provide: A method of detecting a discontinuity in a solar array comprising: locating a detecting device in one or more working positions along the solar array; inducing a signal by applying a plurality of flashes of light, which turn on and off at a desired frequency, to a solar module in the solar array; measuring the signal at two different locations along the solar array; comparing the signals measured at two different locations to each other; and outputting a result of the comparing step.

The detection device of the present teachings comprises: a signal detector for measuring the signal in two or more locations on along a solar array; and a processor that compares the two or more measured signals to each other and provides an output indicating whether the two or more measured signals are outside a predetermined range.

The teachings herein surprisingly solve one or more of these problems by providing an output regarding whether the tested locations are continuous, discontinuous, or partially discontinuous. The teachings herein have a detection device and method that are free of electrical contact with the solar array so that the detection device can test locations without being in electrical contact with the solar array. The teachings herein provide a detection device that is portable so that all of the pieces of the device may be located proximate to the solar array. The teachings herein provide a method of tuning a detection device with the solar array so that the signal from a signal source, a signal measured by the signal detector, or both may be adjusted so that discontinuities and/or partial discontinuities are detected by the detecting device.

### BRIEF DESCRIPTION OF THE DRAWINGS

FIG. 1 illustrates one example of a solar array;

FIG. 2 illustrates one possible electrical connector between two solar modules;

FIG. 3 illustrates one possible buss configuration of a solar module;

FIG. 4 illustrates one possible integrated flashing piece;

FIG. 5 illustrates one possible configuration for a signal stimulus and housing;

FIG. 6A-6B illustrates possible detection devices of the teachings herein;

FIG. 7 illustrates one possible flow diagram, for testing a connection;

FIG. 8 illustrates a detection device in a working position;

FIG. 9 illustrates one possible circuit diagram for the signal detector; and

FIG. 10 illustrates one possible circuit diagram for the signal stimulus.

### DETAILED DESCRIPTION

The explanations and illustrations presented herein are intended to acquaint others skilled in the art with the teachings, its principles, and its practical application. Those skilled in the art may adapt and apply the teachings in its numerous forms, as may be best suited to the requirements of a particular use. Specific embodiments of the present teachings as set forth are not intended as being exhaustive or limiting. The scope of the teachings should be determined not with reference to the above description, but should instead be determined with reference to the appended claims, along with the full scope of equivalents to which such claims are entitled. The disclosures of all articles and references, including patent applications and publications, are incorporated by reference for all purposes. Other combinations are also possible as will be gleaned from the following claims, which are also hereby incorporated by reference into this written description.

Generally a solar array taught herein includes: one or more rows of solar modules and each row includes a plurality of solar modules connected together. Each solar module in the row has a connector on each side that physically and electrically connects the first buss and the second buss of each solar module together so that power passes though the adjoining solar modules. The solar modules on the ends of each row are connected together by an integrated flashing piece so that two adjacent rows are electrically connected. The first solar module in the solar array is electrically connected to an inverter so that the inverter can convert the current into a usable power source. The last solar module in the solar array includes an integrated flashing piece that connects the first buss and the second buss of the last solar module electrically together so that power from the first buss is returned towards the inverter through the second buss. Over time, due to environmental conditions such as temperature variations, wind, rain, snow, debris, the like, or a combination thereof, one or more of the connections detailed above in the solar array may fail so that current at the inverter is reduced and/or eliminated. The teachings herein provide a method and apparatus to test each connection point and/or locate a proximate location of a discontinuity in the solar array so that the connection can be repaired.

The detection device includes at least a signal stimulus and a signal detector. The signal stimulus may be any stimulus that produces a signal through the solar array. The signal stimulus may be any stimulus that is free of direct electrical contact with the solar array. The signal stimulus may be any stimulus that produces a signal having a sinusoidal voltage waveform with a frequency that is transmitted through the solar array. Preferably, the signal stimulus may provide a square voltage waveform that is transmitted through the solar array. More preferably, the signal stimulus may induce a square voltage waveform that passes through the solar array and the signal generates a radiated energy with the same waveform. The signal stimulus may be fully on or fully off and so that a square voltage waveform is produced. The signal stimulus may induce a signal through the solar module so that a radiated energy signal may be produced by the solar module. The radiated energy may substantially mirror the signal created as discussed herein (i.e., frequency, bandwidth, amplitude, sinusoidal waveform, square waveform, the like, or a combination thereof). For example, if the signal has a frequency of about 1000 Hz then the radiated energy will have a frequency of about 1000 Hz. The signal stimulus may be any stimulus that may be tuned. For example, the frequency of the signal may be varied, adjusted, or both. Preferably, the signal stimulus is one or more lights that flash simultaneously, which are located proximate to and detected by one or more solar modules so that a signal with a square voltage waveform, a sine wave, a quasi-sine wave, or a combination thereof is generated through the solar array. For example, the lights flash on and off causing a square waveform, but the properties of the solar modules, the band pass filter, of both may cause corners of the square wave to be rounded so that a quasi-sine wave may pass through the solar array and/or detector device. More preferably, the signal stimulus is one or more lights (e.g., strobe light) placed over at least one solar module that flashes at a frequency that may be measured by the detection device. The signal stimulus may have a sufficient amount of light and/or power so that the solar module detects the light and produces a signal that is detectable by a detector.

The signal stimulus may have a sufficient amount of lights so that the lights produce enough power that a signal is induced in the solar array. The signal stimulus preferably, includes one or more of lights coupled together so that the lights act as one larger light source. The one or more lights may produce about 100 W/m² or more, about 200 W/m² or more, preferably about 300 W/m² or more, more preferably about 400 W/m² or more, or more preferably about 500 W/m² or more of light. The one or more lights may produce about 2,000 W/m² or less, about 1,500 W/m² or less, or about 1,000 W/m² or less. The one or more of lights may be located in a housing. The housing may be any component that blocks ambient light sources from reaching the solar module. The housing may be any component that may be placed over a solar module so that all other light sources are blocked and the only light source detected by the at least one solar module is the signal stimulus. The housing may block the other light sources so that the frequency of the signal stimulus is clearly introduced to the solar array. The signal stimulus includes a controller to regulate the frequency of the lights turning on and off. The controller may include one or more of the following components: diodes, resistors, batteries, capacitors, metals oxide semiconductor field effect transistors, printed circuit boards, light emitting diodes, on/off switches, operational amplifiers, potentiometers, an integrated circuit timer, or a combination thereof so that the controller induces a waveform with a frequency through the solar array. The components may be arranged in any configuration so that the components control the speed and/or frequency lights turning on and off. The operational amplifiers may be any operational amplifier. Preferably, the operational amplifier is a quad operational amplifier or an equivalent. More preferably, the operation amplifier is an LM324. The strobe circuit may be any strobe circuit that may cause the lights to turn on and off. Preferably, the strobe circuit is an LM555 integrated circuit timer. Most preferably, the components may be configured so that the controller causes the signal stimulus to turn on and off at a frequency.

The frequency induced by the signal stimulus may be any frequency that may be detected by the detector so that a discontinuity, a partial discontinuity, or continuity may be determined at the location on the solar array being tested. The frequency may be any frequency so that an alternating signal may be induced through the solar module that induces a radiated energy with a frequency that may be measured proximate to the solar module. The frequency may be adjusted by changing the rate at which the light flashes. The frequency, bandwidth, or both may be adjusted so that the signal strength may be increased and the signal detector may provide a more accurate reading, filter the “noise” out and detect the signal, or both. For example, the signal stimulus may provide a signal with a frequency to one or more solar modules and one or more adjacent solar modules may receive light that may introduce a second signal with a second frequency into the solar array, and the signal detector may filter out the second signal and/or the signal detector may be tuned to only recognize a signal within the first signal's frequency. In another example, surrounding electrical devices may produce a frequency that may be detected by the signal detector and the signal, the signal detector, or both may be tuned to avoid those frequencies (e.g., about 60 Hz and about 120 Hz). The frequency may be any frequency that is detectable by the signal detector. The frequency may be any frequency that is different from the frequency of the surrounding tight sources. The signal stimulus may produce a signal with a frequency of greater than about 0 Hz, about 1 Hz or more, preferably about 10 Hz or more, or more preferably about 100 Hz or more. The signal stimulus may produce a signal with a frequency of about 50,000 Hz or less, preferably about 10,000 Hz or less, most preferably about 5,000 Hz or less. The signal stimulus may produce a signal with a frequency in a range of 50,000 Hz to about 0 Hz, preferably from about 10,000 Hz to about 1 Hz, more preferably from about 5,000 Hz to about 10 Hz (i.e., about 1,000 Hz or less, but greater than 100 Hz). The signal produced has a bandwidth.

The bandwidth may be any range of frequencies so that the bandwidth may be detected by the signal detector. The bandwidth as discussed herein is a pass band indicating the frequency of the signal that may pass through the solar array. The bandwidth may be varied. The bandwidth is a range of frequencies where the signal and/or radiated energy may be detected by a signal detector. Preferably, the bandwidth is substantially similar to the frequencies recited herein. The bandwidth may be greater than about 0 Hz, about 0.1 Hz or more, preferably about 1 Hz or more, or more preferably about 10 Hz or more. The bandwidth may be about 50,000 Hz or less, preferably about 10,000 Hz or less, most preferably about 5,000 Hz or less. The bandwidth may be in a range of 50,000 Hz to about 0 Hz, preferably from about 10,000 Hz to about 1 Hz, more preferably from about 5.000 Hz to about 10 Hz (i.e., about 1,000 Hz or less, but greater than 100 Hz). The signal has an amplitude within the bandwidth and/or frequency.

The amplitude may be at its largest when the amplitude is within the bandwidth. The amplitude may decrease as the frequency becomes further and further from the bandwidth discussed herein. For example, if amplitude is largest within a bandwidth range from about 0.1 Hz to 4,000 Hz and the frequency of the signal is about 8,000 Hz the amplitude may be a factor of two times or more smaller as compared to the amplitude within the bandwidth. The amplitude may be substantially constant when the frequency is within the bandwidth discussed herein. The signal may have sufficient amplitude so that the radiated energy is measured when the signal detector is located proximate to one or more solar modules. The amplitude of the signal may be about 1.0 db or more, preferably about 2.0 db or more, or more preferably about 2.5 db or more. The amplitude may be about 10 db or less, preferably about 8.0 db or less, or more preferably about 5.0 db or less (i.e., about 3.0 db). Most preferably, the frequency and the bandwidth of one or more solar modules in a solar array may be selected so the amplitude of the signal is large and the signal may be measured using the method taught herein, and a signal detector taught herein may be used to detect the signal generated so that discontinuities and partial discontinuities in the solar array are detected. The amplitude may be increased and/or decreased by adjusting gain of the signal detector.

The signal detector may include a sufficient amount of gain control so that the signal input may be increased and measured so that the status of a connection may be determined. The gain may be varied by a factor of two or more, three or more, four or more, or even five or more. The gain may be varied by a factor of ten or less, of eight or less, or six or less. The gain may remain substantially constant from measurement to measurement. The gain may be varied so that a radiated energy may be detectable over surrounding noise. The gain may be adjusted as the signal detector moves away from the signal stimulus. The gain may be adjusted so that the signal detector may be used as a non-contact signal detector.

The signal detector is a detection device that may measure a signal at a location without being electrically connected to the solar array. The signal detector is a non-contact detection device. The signal detector includes one or more antennas for detecting the signal being generated. The antennas may be any antenna that may, without an electrical connection, detect the signal being generated. Preferably, the detection device includes at least two antennas for detecting the signal being generated. More preferably, the signal detector detects the signal being generated my measuring radiated energy created by the signal passing through the one or more solar modules. The two antennas may be used to simultaneously detect the signal being generated by measuring radiated energy at two different locations. The two antennas may be used sequentially to detect the signal being generated. The signal when detected may be measured by a processing unit.

The processing unit may be any processor that may be used to determine the status of the location being measured (i.e., continuous, discontinuous, or partially discontinuous). The processing unit may be a processor, a microprocessor, microcontroller, the like, or a combination thereof. Preferably, the processing unit includes a microcontroller available from Atmel ATMEGA328P-PU. More preferably, the processing unit includes an analog to digital converter. The processing unit may be capable of comparing two or more signals to determine a status. The processing unity may include an algorithm that may be used to determine the status of the signal. The algorithm may directly compare two or more signals together to determine the status at the locations being measured. Preferably, the controller, microprocessor, microcontroller, or a combination thereof subtracts a second measured signal value from a first measured signal value and compares an absolute difference between the two values to a predetermined level. If the difference is below the predetermined level then the output indicates that the connection is good or continuous. If the difference is above the predetermined level then the output indicates that the connection is bad or discontinuous.

The predetermined level may be calculated by the signal detector during detection. Preferably, the predetermined level may be calculated and input into the processor, the microcontroller, or both. The predetermined level may be calculated based upon voltage, amperage, radiated energy, or a combination thereof. Preferably, the predetermined level is calculated using a filtered voltage signal. The predetermined level may be calculated based upon the maximum voltage, maximum amperage, maximum radiated energy, or a combination thereof through the system divided by the maximum voltage drop, maximum amperage drop, maximum radiated energy drop, or a combination thereof across any point along the solar array. The predetermined level may be about 20 percent or less, about 15 percent or less about 10 percent or less, or even about 5 percent or less a maximum voltage level, maximum amperage level, a maximum radiated energy level, or a combination thereof. For example, a maximum voltage signal in a solar module, a connector, an integrated flashing piece, or a combination thereof may be measured; and a maximum voltage drop of a solar module, a connector, an integrated flashing piece, or a combination thereof may be measured. The maximum voltage signal and the maximum voltage drop may be fed into the microcontroller and the microcontroller may convert the analog signal to a digital signal using the microcontroller's analog to digital converter. Preferably, the analog to digital convert is a 10 bit analog to digital converter (ADC). The DC signals may be compared to a range of counts where 0 count is equal to 0 volts and 1024 counts is equal to 5 volts to determine the counts within the range. The reference voltage versus the counts of the ADC may be varied depending on the voltage range of the DC voltage level. The reference voltage may be 1 volt or more, 2 volts or more, or 3 volts or more. The reference voltage may be 10 volts or less, 8 volts or less, or 6 volts or less. Thus, if the reference voltage is 2 volts the reference voltage is equal to 1024 counts. In another example, if the reference voltage is 5 volts (i.e., 1024 count) and the largest voltage measured at any point along the solar array is 1.5 volts (i.e., 308 count) and the maximum voltage drop at any point across the solar array is 0.15 volts (i.e., 31 count) the maximum power drop is 10 percent and the predetermined level is 10 percent. Therefore, the predetermined level in this example is 31 counts or 10 percent and any count above 31 counts or 10 percent is discontinuous and any count at or below 31 counts or 10 percent is continuous. The predetermined level may vary from a first buss to a second buss. The predetermined level may vary based upon the connection being measured. For example, the predetermined level may be different for a connector, a solar module, an integrated flashing piece, or a combination thereof. The signal detector may have a mode selector that may be changed based upon the connection being tested so that an accurate predetermined level is used for comparison. The predetermined level may be the same for all of the components and all of the busses. The microprocessor may include an algorithm that adjusts the predetermined level based upon the selection by the user.

The algorithm may be programmed to account for the distance of each measurement from the signal stimulus, the amount of gain being applied, for resistance and/or impedance between the two testing locations, or a combination thereof. For example, as locations are tested further and further from the signal stimulus the signal strength may gradually reduce and the algorithm may be used to determine the amount each measurement should reduce due to the distance from the signal stimulus and the processor may factor this difference into the comparison of two or more signals. The processing unit may use an algorithm to calculate a signal strength at a given location and compare the calculated signal to the actual signal measurement to determine the status of the location. The processing unit may include memory. The processing unit may include a sufficient amount of memory so that the processing unit can store at least two measurements, an algorithm, or both. The processing unit may include memory so that a first measurement may be taken at a first location and a second location may be subsequently made at a second location and then the two compared.

The signal detector includes one or more output devices. The output device may output an auditory signal, a visual signal, a haptic signal, or a combination thereof. Preferably, the output device outputs a signal that is free of interpretation by the user. For example, it is preferred that the output device does not output a sound that varies depending upon the signal strength and the user determines whether the signal strength has changed based upon the changes in sound. More preferably, the output device provides an output indicating whether the measured location is continuous, discontinuous, or partially discontinuous. For example, the output device lights a green light when the signal is continuous, a red light when the signal is discontinuous, and both red and green lights when the signal is partially discontinuous. The output device may output a display screen that states, open, closed, continuous, discontinuous, partially discontinuous, or a combination thereof.

The detecting device is used in a method described herein so that the status of the solar modules, connections between solar modules, the connections between solar modules and integrated flashing pieces, connections with the inverter, or a combination thereof along the solar array may be checked so that discontinuities and/or partial discontinuities in the solar array are located and repaired. The method may include one or more of the steps discussed herein performed in any order. The method includes a step of locating the signal detector, the signal stimulus, or both at one or more working positions along the solar array. The working positions may be at any location along a solar array where discontinuities or partial discontinuities may be located. Preferably, the working positions may be at one or both ends of a solar module. The signal detector maybe moved from connection to connection so that each individual connection may be tested. The signal stimulus may be moved from solar module to solar module and preferably from row to row and the connections of the solar array are tested. The working positions may be along a first bus, a second buss, or both. The method includes a step of moving the detecting device to different working positions along the solar array. The working positions may be connections between the solar modules, connections within solar modules, the first buss, the second buss, connections between the solar module and the integrated flashing pieces, connections between a solar module and the inverter, or a combination thereof. The step of moving may be repeated until the detecting device detects a discontinuity and/or a partial discontinuity. The step of moving may be repeated until the signal is lost. The signal detector may test a connection and determine the status of that connection individually (e.g., continuous, discontinuous, or partially discontinuous). The signal detector may measure the signal and/or radiated energy produced by the signal at two or more points simultaneously, sequentially, or both and determine the status of a connection. The signal detector may compare the measured signal at the one or more working positions to each other, to a theoretical signal measurement, to a calculated signal measurement, or a combination thereof.

The signal detector may process the signals before providing an output regarding the signal. The antenna measures a signal through the radiated energy. The antenna may pass the signal through an amplifier and/or pre-amplifier. The amplified signal may be filtered. The filter may remove all signals outside of a predetermined bandwidth. The filter may remove all signals within a predetermined bandwidth. The filtered signal may be adjusted up and/or down so that the signal strength may be increased and/or decreased. The gain of the filtered signal may be adjusted so that the signal is within a predetermined range. After the signal is filtered and the amplitude of the signal is adjusted by adjusting the gain. The method may include a step of passing the signal through a level shifting phase and output filter. The signal may be output to the microprocessor so that the signals may be compared. The signal may go through one or more of the steps herein so that the signals may be compared to each other and the status of one or more connections determined. Analog circuitry may convert the signal from an alternating current signal to a direct current signal that may be proportional to the radiated signal strength so that the signals may be read by the processor, microprocessor, microcontroller, or a combination thereof and compared. The processor, microprocessor, microcontroller, or a combination thereof may compare two alternating signals together. The processor and/or microprocessor may adjust one or more signals based upon a predetermined resistance factor, impedance factor, or both (e.g., the amount the signal will decrease as the signal detector is moved away from the signal stimulus). The signal may be compared to a calculated signal strength and/or theoretical signal strength.

To calculate a signal measurement the signal detector may require a user to input the number of solar modules between the working position and the signal stimulus, input the number of solar modules between the inverter and the working position, input the number of solar modules in a row, input the number of solar modules in the solar array, or a combination thereof. The signal detector may determine a calculated signal measurement at the working position based on one or more of the input information and the calculated signal measurement may be compared to the signal measurement to determine the status of a connection.

Preferably, the processor and/or microprocessor compare two or more signals together to determine the status of the connections. The processor and/or microprocessor may have predetermined difference between measurements based upon the measurements being compared. For example, a first buss may have a smaller predetermined difference than a second buss. More specifically, the length of the second buss may span the length of a row and the second buss may be tested at a first end of a row and a second end of the row, and the first buss may be tested at a first end of a solar module and a second end of a solar module so that the resistance and/or impedance is smaller in the first buss than the second buss resulting in a smaller predetermined difference range. The predetermined difference between the first measurement and the second measurement may be about 20 percent or less, about 15 percent or less, about 10 percent or less, or about 5 percent or less. The predetermined difference may be from about 20 percent to about 0 percent and preferably from about 10 percent to about 0 percent. Thus, for example, if the measured value of the two points is within about 10 percent and 0 percent then the connection is continuous, and difference between the two measurements is greater than 10 percent the connection may be partially discontinuous and/or discontinuous.

The status at a working position may be output by the detecting device. The detecting device may output a result based upon the comparison of the measured signal. The device may indicate whether each of the working positions are continuous, discontinuous, or partially discontinuous. The device may have a step of outputting a first light, a second light, or both to indicate the status of a test location. The signal detector may have a step of outputting a first number of vibrations to indicate a first status and a second number of vibrations to indicate a second status and so on.

The method includes a step of inducing a signal within the solar array. The signal may be induced by applying a stimulus to a solar module. The signal may be induced by any device that produces a signal in the solar module without being electrically connected to the solar array. Preferably the signal is induced by applying a non-contact signal stimulus to a solar module so that a continuous signal is created throughout the solar array. More preferably, the signal is induced by simultaneously flashing one or more lights located proximate to a solar module so that a signal with a frequency equivalent to the frequency of the one or more flashing lights is induced through the solar array. The signal stimulus may be moved from solar module to solar module as each solar module and connection is tested. The signal stimulus may remain static as each connection is tested. The signal stimulus may be tuned before the signal stimulus is applied to a solar module so that the signal may be detected by the signal detector.

The signal stimulus may be tuned using one or more of the steps herein so that the signal stimulus provides a signal within a detectable range of the solar module so that a signal in the form of a square voltage waveform passes through the solar module. The frequency response of one or more solar modules in a solar array, one or more comparable solar modules, or both may be measured. Preferably, the frequency response of a comparable solar module may be determined so that the frequency response is determined in the laboratory as opposed to the field. A comparable solar module may be a solar module made of the same materials as the solar modules in the solar array, a solar module from the same manufacturer, or both. The frequency response of a solar module, a row, a solar array, or a combination thereof may be measured so that a signal stimulus may be tuned and a frequency, bandwidth, amplitude, or a combination thereof of a sinusoidal voltage waveform, a square voltage waveform, or both may be transmitted along a solar module, row, solar array, or a combination thereof. A solar module, a row, a solar array, or a combination thereof may be connected to a function generator, a resistor, an oscilloscope, or a combination thereof.

The function generator may provide a waveform to the solar module, row, solar array, or a combination thereof that may pass through the solar module, row, solar array, or a combination thereof and be received by an oscilloscope. The waveform produced by the function generator may have different alternating forms. Preferably, the waveform produced by the function generator is a constant sinusoidal voltage waveform that may be similar in frequency, bandwidth, amplitude, or a combination thereof to a voltage signal and/or radiated energy produced by the signal stimulus. The function generator may vary the bandwidth, frequency, type, or a combination thereof of the waveform being applied to the solar module, row, solar array, or a combination thereof. The peak to peak output of the function generator may be varied during the tuning step. The peak to peak output may be about 0.1 V or more, about 0.3 V or more, or about 0.5 V or more. The peak to peak output may be about 2.0 V or less, about 1.5 V or less, or about 1.0 V or less (i.e., about 0.8V). The frequency of the waveform may be varied so that the detectable range passing through the solar module, row, solar array, or a combination thereof may be determined.

The frequency of the waveform passed through the solar module, row, solar array, or a combination thereof may be any frequency that may be detected by a signal detector, an oscilloscope, or both. The waveform may have any frequency and/or bandwidth discussed herein for the signal stimulus. Thus, the frequency and/or bandwidth determined in the step of determining the frequency response of a solar module, a row, a solar array, or a combination thereof may be used to tune the signal stimulus so that the signal is detectable by the detection device. As the frequency is varied the bandwidth of the waveform may be monitored. The frequency, bandwidth, or both may be monitored using an oscilloscope. The bandwidth may be monitored so that a bandwidth may be selected where the amplitude is at its maximum. A bandwidth may be selected where the amplitude is large, is within a detectable range of the signal detector, or both. The waveform from the function generator may pass through one or more resistors before entering the solar module, the row, the solar array, or a combination thereof.

The resistor preferably is located between the function generator and a solar module. The resistor may be any size resistor. The resistor may stabilize the signal from the function generator so that the oscilloscope may detect the waveform being produced. The resistor may stabilize the amplitude output of the function generator within a frequency range so that the bandwidth, frequency, or both of the waveform measured across the solar module remains substantially constant. The resistor may be sufficiently sized so that the resistor provides a divider in the circuit so that changing impedance of the module may be measured as the frequency is changed, a minimal load is provided on the function generator in addition to the impedance of the solar module, the function generator may output a constant amplitude over a frequency range so that a load will not drop below an output impedance of the function generator, or a combination thereof. The resistor may be substantially equal to the voltage output of the function generator. The resistor may be about 10Ω or more, about 20Ω or more, about 30Ω or more, or about 40Ω or more. The resistor may be about 100Ω or less, about 90Ω or less, about 80Ω or less, about 70Ω or less, or about 60Ω or less (I.e., about 49Ω).

After the frequency range, bandwidth, or both of the one or more solar modules is determined the signal stimulus is tuned so that the signal stimulus outputs a signal within the frequency range, the bandwidth range, or both. For example, the speed that the lights of the signal stimulus are adjusted so that a signal outputted by the solar module has a square voltage waveform with a frequency, bandwidth, amplitude or a combination thereof within the determined ranges.

The method of testing connections within the solar array may be performed with the signal detector, the signal stimulus, or both proximate to the solar array. Preferably, the method is performed with the signal detector and the signal stimulus in close vicinity to each other. More preferably, the method is performed where both the signal detector and the signal stimulus are located within an area of the solar array. For example, the signal stimulus may be covering one solar module and the signal detector may be at working position at the same or another solar module in the solar array. Preferably, the method is performed with the solar array being disconnected from the inverter. The working location of both the signal stimulus and the signal detector may be any location where the solar array is located. The working location of the signal stimulus and the signal detector may be a roof of a house or a building, proximate to a factory, proximate to an airport, or a combination thereof.

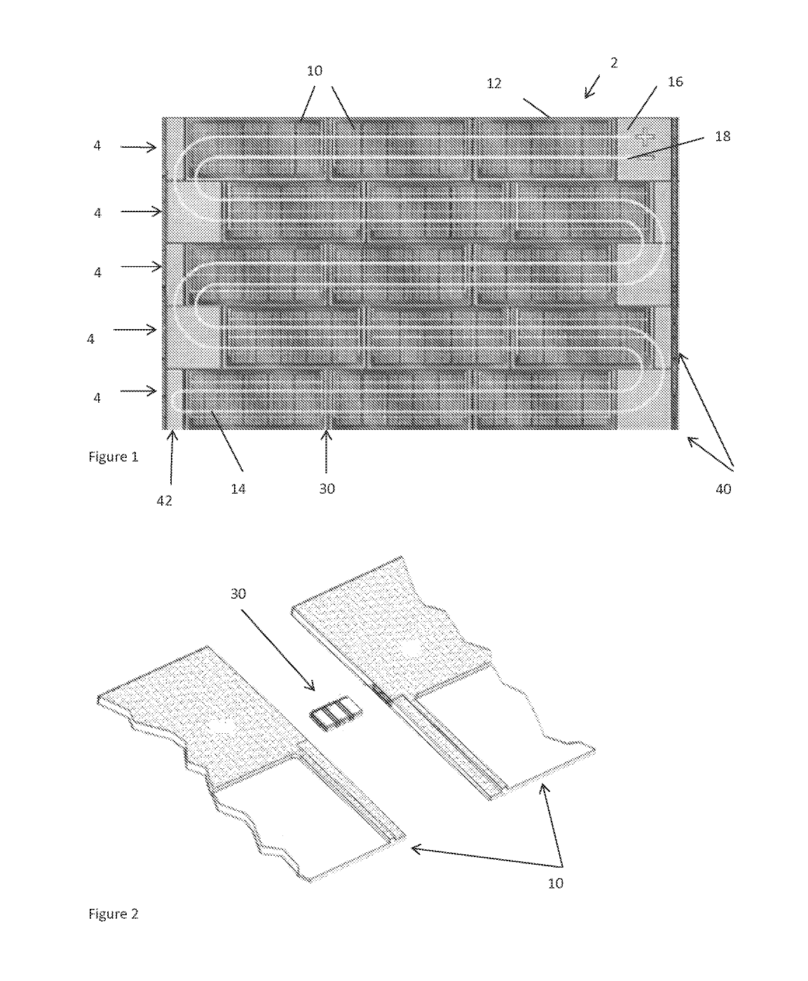

FIG. 1 illustrates a solar array 2. The solar array includes a plurality of solar modules 10. Each solar module 10 is connected to an adjacent solar module by a connector 30. A row of solar modules 10 connected together form a row 4. The ends of the rows 4 include an integrated flashing piece 40 that connects the adjoining rows 4 together so that a solar array is formed 2. The first solar module 12 is connected to an inventor (not shown) so that the power generated by the solar array may be used. The last solar module 14 is connected to a single integrated flashing piece 42 that connects a first buss 16 and a second buss 18 of a solar module together so that power is directed towards the inverter (not shown).

FIG. 2 illustrates one possible connector 30 that may be used to connect to solar modules 10.

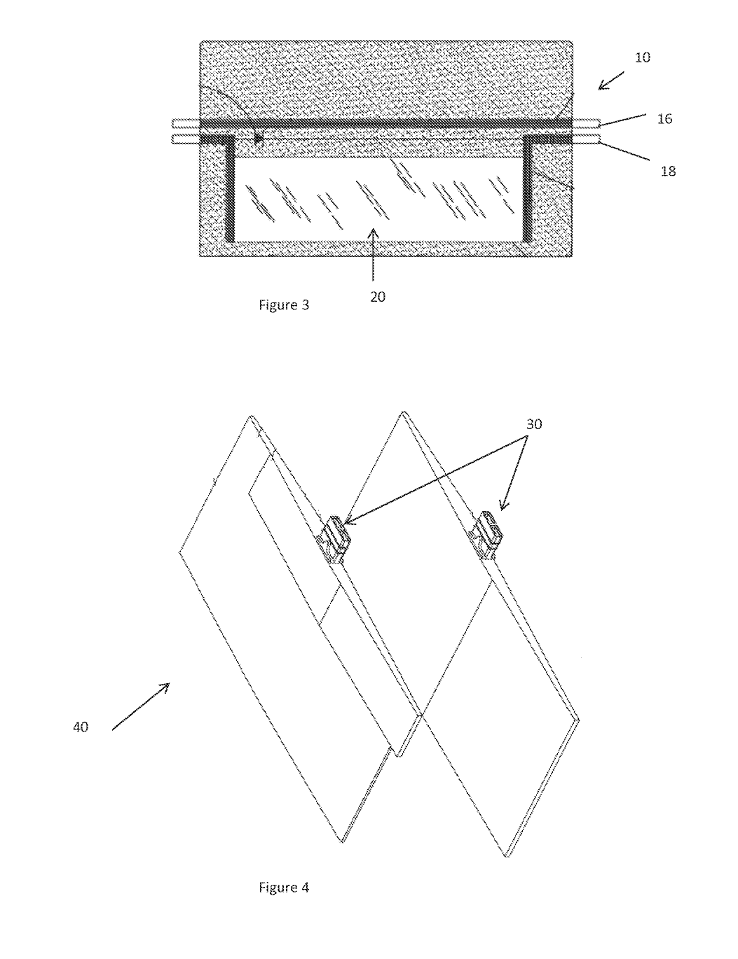

FIG. 3 illustrates a solar module 10 having a first buss 16 and a second buss 18. The first buss 16 passes directly through the solar module 10 and the second buss 18 extends along the body portion 20 so that power can be passed to the second buss 18 and through a connector (not shown).

FIG. 4 illustrates an integrated flashing piece 40. The Integrated flashing piece 40 connects to adjacent rows 4 so that power flows from one row to another and to the inverter (not shown).

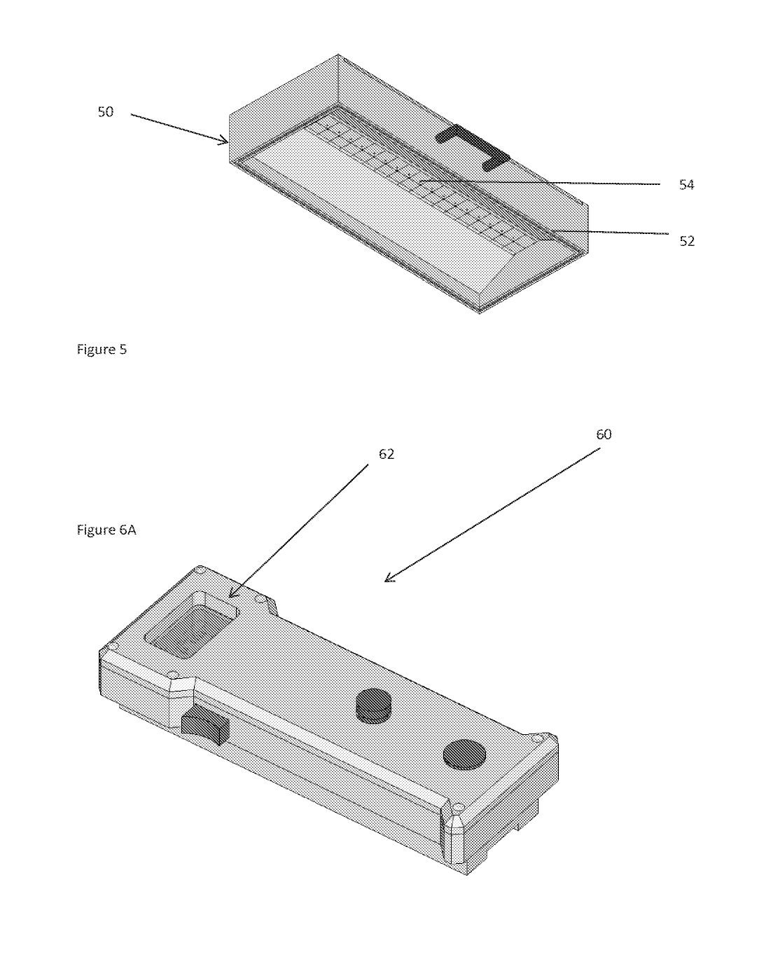

FIG. 5 illustrates one possible signal stimulus 50. The signal stimulus has a housing 52 and lights 54. During use the signal stimulus 50 covers the solar module 10 and the lights 54 flash so that a signal is induced through the solar module 10 and the solar array (not shown).

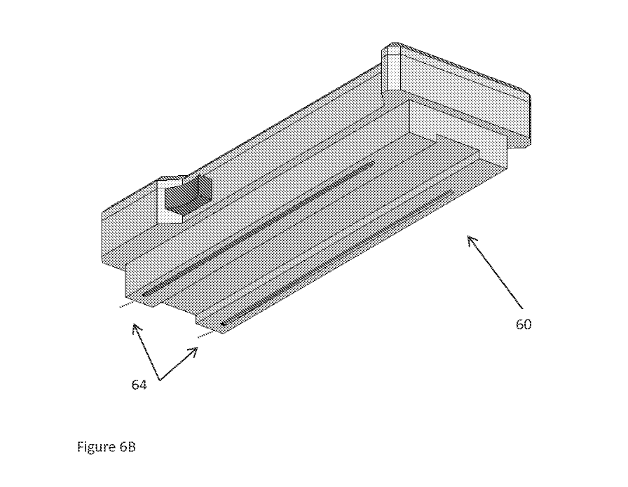

FIG. 6A illustrates a top perspective view of one possible signal detector 60. The signal detector as show includes an output screen 62 and a pair of antennas (not shown) for detecting discontinuity or partial discontinuity. FIG. 68 illustrates a bottom perspective view of one possible signal detector 60. The signal detector includes a pair of antennas 84.

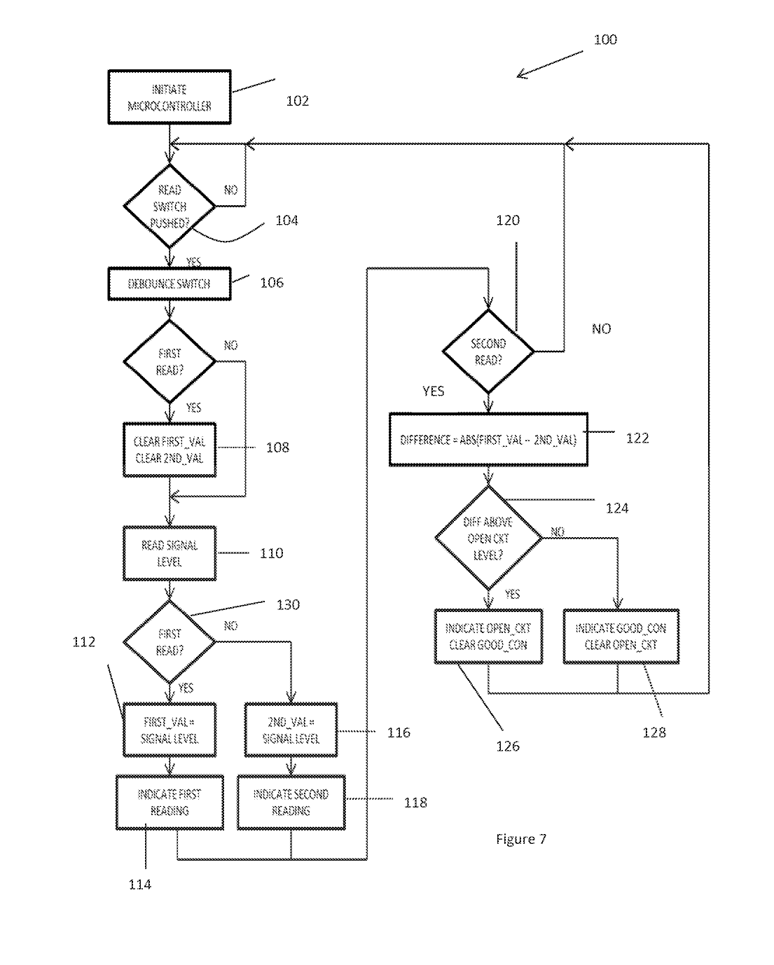

FIG. 7 illustrates one possible flow diagram 100 for testing a connection. The flow diagram 100 as illustrated describes taking two readings sequentially. The signal detector begins to function once the microcontroller is initiated 102 so that the microcontroller clears its memory and activates outputs. Monitors the read switch 104 to determine whether it has been activated. The read switch 104 is debounced 106 in the event that the read switch 104 is internally activated multiple times. The signal detector clears its memory 108 if both a first reading and a second reading are present. If no readings are stored in memory the signal detector reads a first signal level 110 using stronger signal between the two antennas. The first signal level 110 once read is converted into a first value 112 and stored in memory 114 as the first reading and displays in the output screen (not shown) that a reading has been taken. Once a first signal is measured and stored in memory the processor checks for a second signal 120. If a second signal is present the process proceeds to determine the difference between the first signal and the second signal 122. If only one reading is stored in memory then the processor proceeds back to determining whether the read switch 104 has been pushed and steps 104 through 110 are repeated. The processor checks the memory for a first reading 103 and if the first reading is present the processes the reading as a second reading and converts the second reading into a second value 116 and stores the second value in memory 118 as the second reading. Once both readings are measured the step 120 determined that “YES” the second reading is present and proceeds to step 122. The microcontroller subtracts the first value from the second value generating a difference 122. The difference 122 is compared to a predetermined value 124. If the difference 122 is greater than the predetermined value 124 then the circuit is discontinuous 126. If the difference 122 is less than the predetermined value 124 then the circuit is continuous 128. After the signal detector provides the status of the connection the microprocessor reverts to step 104 and monitors the read switch.

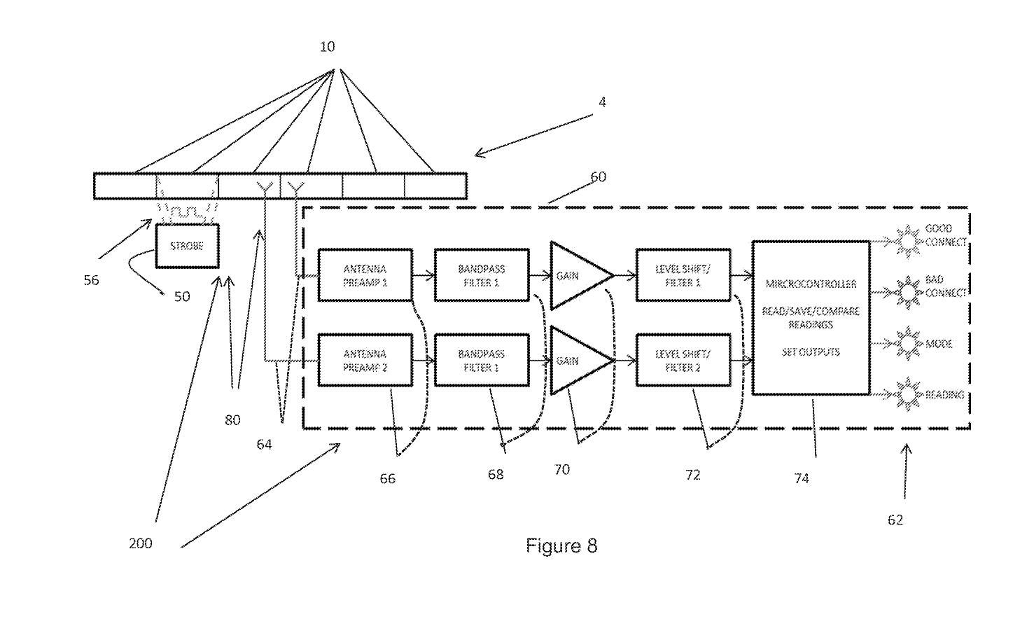

FIG. 8 illustrates a detection device 200 includes a signal stimulus 50 and a signal detector 60 in electrical communication with a row 4 of solar modules 10. The row 4 as illustrated has been disconnected from the inverter (not shown). The signal stimulus 50 is located proximate to a solar module 10 and induces a signal 56 that that passes through the row 4. The signal detector 60 has antenna 64 that are located at working positions 80 along the row 4 so that the connections may be tested. The signal detector 60 includes an amplifier 66 for each antenna 64. The amplified signal is passed through a bandpass filter 68 and then a gain filter 70 so that the amplitude of the signal is adjusted. The signal passes through a level shift filter 72 so that the circuit can convert an alternating signal into a direct signal and the filtered signal is passed into the microcontroller 74 where the microcontroller determines the status of the connection. One possible test method that may be performed by the microcontroller 74 is discussed with FIG. 7. Finally, the status of the connection, the current status of the signal detector 60, or mode of the signal detector 60 is listed in the display screen 62.

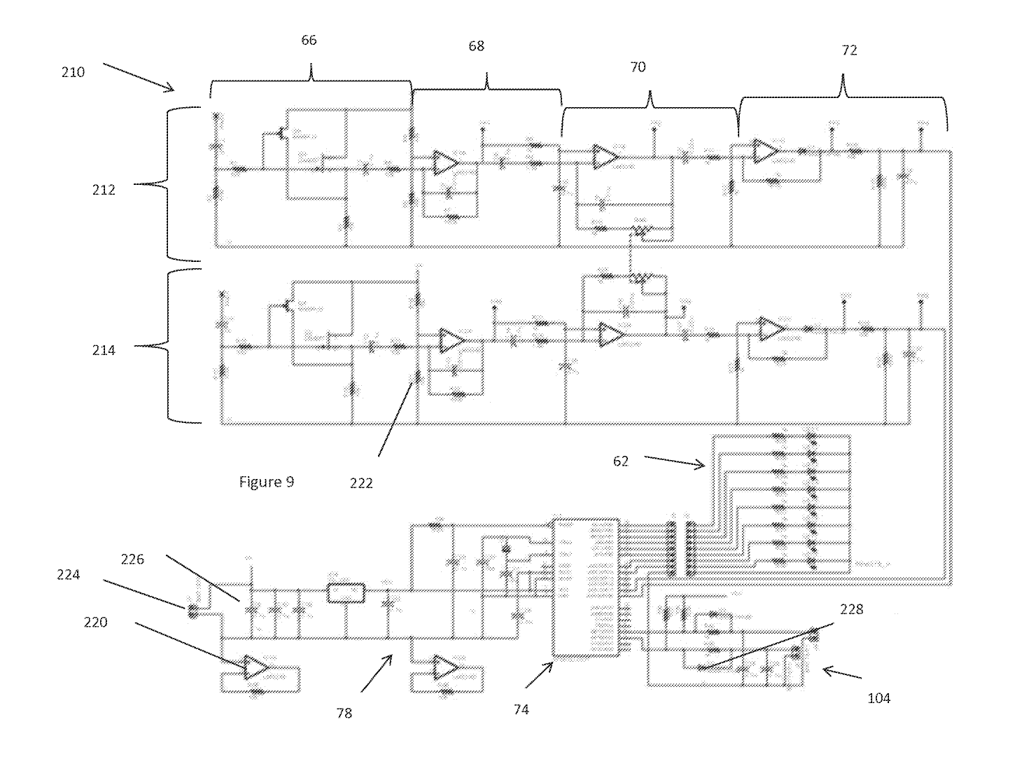

FIG. 9 illustrates one example of a circuit diagram 210 for the signal detector 60. The circuit diagram 210 has a first circuit 212 for the first antenna and a second circuit 214 for the second antenna. Both the first circuit 212 and the second circuit 214 include an amplifier 66, a bandpass filter 68, gain 70, and a level shift filter 72. The first circuit 212 and the second circuit 214 are connected to the microcontroller 74. The microcontroller 74 is connected to a read switch 104 so that when the read switch 104 is pressed the antenna measure a signal through the first circuit 212 and the second signal 214. The microcontroller 74 outputs a display through the output screen 62. The circuit diagram 210 illustrates one configuration for the location of operational amplifiers 220, resistors 222, and capacitors 226 so that the circuit diagram measures signals and provides the status of the connection. Only one operational amplifier 220, resistor 222, capacitor 226, and diode 228 have been labeled for clarity of the diagram. The signal detector is attached to a battery 224 that powers the circuit 210 via the supply circuit 78.

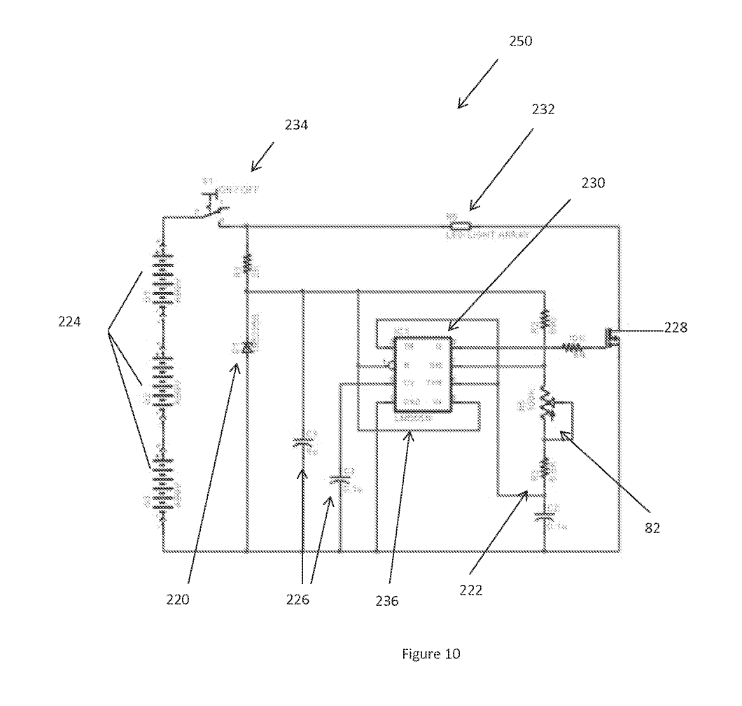

FIG. 10 illustrates one example of a circuit diagram 250 for the signal stimulus 50. The circuit includes zener diode 238, resistors 222, batteries 224, capacitors 226, a metal oxide semiconductor field effect transistor (MOSET), Light Emitting Diodes (LED) 232, and an on/off switch 234. The signal stimulus 50 circuit 250 uses a potentiometer 82 and an integrated circuit timer 236 to adjust the frequency of the LEDs 232 turning on and off.

Any numerical values recited herein include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

Unless otherwise stated, all ranges include both endpoints and all numbers between the endpoints. The use of “about” or “approximately” in connection with a range applies to both ends of the range. Thus, “about 20 to 30” is intended to cover “about 20 to about 30”, inclusive of at least the specified endpoints.

The term “consisting essentially of” to describe a combination shall include the elements, ingredients, components or steps identified, and such other elements ingredients, components or steps that do not materially affect the basic and novel characteristics of the combination. The use of the terms “comprising” or “including” to describe combinations of elements, ingredients, components or steps herein also contemplates embodiments that consist essentially of the elements, ingredients, components or steps. By use of the term “may” herein, it is intended that any described attributes that “may” be included are optional.

Plural elements, ingredients, components or steps can be provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps.

It is understood that the above description is intended to be illustrative and not restrictive. Many embodiments as well as many applications besides the examples provided will be apparent to those of skill in the art upon reading the above description. The scope of the teachings should, therefore, be determined not with reference to the above description, but should instead be determined with reference to the appended claims, along with the full scope of equivalents to which such claims are entitled. The omission in the following claims of any aspect of subject matter that is disclosed herein is not a disclaimer of such subject matter, nor should it be regarded that the inventors did not consider such subject matter to be part of the disclosed inventive subject matter.

We claim:

1. A method of detecting a discontinuity in a solar array comprised of a plurality of solar modules, the method comprising:
a. locating a detecting device in one or more working positions along the solar array;
b. inducing a signal by applying a plurality of flashes of light, which turn on and off at a desired frequency, to a solar module in the solar array;
c. measuring the signal at a first location on the solar array with the detecting device;
d. measuring the signal at a second location on the solar array with the detecting device
e. comparing the signals measured at the first location to the second location; outputting a result of the comparing step; and
f. moving the detecting device to one or more second working positions on the solar array and repeating steps (c) through (f).

2. The method of claim 1, wherein the method includes the step of determining a frequency range of at least one comparable solar module to a solar module in the solar array so that the plurality of flashes of light flash within the frequency range.

3. The method of claim 1, wherein a strobe light produces the plurality of flashes of light.

4. The method of claim 2, wherein the step of determining the frequency range of the at least one solar module includes one or more of the following steps:
a. stabilizing a resistance of the solar module in the solar array by placing a resistor in series with the solar array;
b. applying a constant sinusoidal voltage waveform to the circuit, the sinusoidal voltage waveform having a frequency in a range of from about 0.1 Hz to about 100,000 Hz;
c. monitoring bandwidth of the sinusoidal voltage waveform;
d. adjusting the frequency of the sinusoidal voltage waveform; and
e. selecting a range of the frequency where the bandwidth of the solar module is in a detectable range.

5. The method of claim 1, wherein an oscilloscope is used to determine the frequency range of the solar module.

6. The method of claim 2, wherein the method includes the step of tuning the strobe light so that the strobe light outputs a signal within the frequency range of the solar module.

7. The method of claim 4, wherein the resistance is selected so that the resistance substantially matches the impedance of a device applying the sinusoidal voltage waveform so that the device does not short out.

8. The method of claim 1, wherein the method detects a discontinuity between solar modules, along a main line, between a solar module and an integrated flashing piece, or a combination thereof.

9. The method of claim 7, wherein the output provides an indication of discontinuity, partial discontinuity, or continuity between the two different locations.

10. The method of claim 1, wherein the detecting device is used without electrically connecting the detecting device to the circuit.

11. The method of claim 1, wherein a detecting device and the strobe light are located in a vicinity of the testing location.

12. The method of claim 10, wherein the testing location and the vicinity are both located on a roof of a house or a building.

13. The method of claim 1, wherein the detecting device comprises:
a processor that compares the two or more measured signals to each other and provides an output indicating whether the two or more measured signals are outside a predetermined range.

14. The method of claim 1, wherein the detecting device includes memory so that a first measurement is stored while the second measurement is taken and the two measurements are compared together.

15. The method of claim 13, wherein the predetermined frequency is from about 0.1 Hz to about 5,000 Hz.

16. The method of claim 1, wherein the detecting device includes two or more antennas that are simultaneously located proximate to two or more working positions so that the signals are compared as the signals are measured.

17. The method of claim 1, wherein the output is visual, auditory, haptic, or a combination thereof.

18. The method of claim 13, wherein the predetermined range of the frequency is a difference between the two or more measurements indicating that the two or more signals are continuous, discontinuous, or partially discontinuous.

19. The method of claim 3, wherein the strobe light comprises a housing that completely covers at least one solar module so that ambient light is not detected by the at least one solar module.
